(19) United States
(12) Patent Application Publication
(10) Pub. No.: US 2025/0072178 A1
(43) Pub. Date: Feb. 27, 2025

(54) DISPLAY PANELS AND MANUFACTURING METHODS THEREOF, AND DISPLAY APPARATUSES

(71) Applicant: Guangzhou China Star Optoelectronics Semiconductor Display Technology Co., LTd., Guangzhou (CN)

(72) Inventor: Guozhong WANG, Guangzhou (CN)

(73) Assignee: Guangzhou China Star Optoelectronics Semiconductor Display Technology Co., LTd., Guangzhou (CN)

(21) Appl. No.: 18/536,035

(22) Filed: Dec. 11, 2023

(30) Foreign Application Priority Data
Aug. 23, 2023 (CN) 202311071583.2

(51) Int. Cl. H01L 33/56; H01L 27/15

(52) U.S. Cl. CPC H01L 33/56; H01L 27/156

(57) ABSTRACT

The present disclosure discloses a display panel and a manufacturing method thereof, and a display apparatus. The display panel includes a panel body and an encapsulation film disposed on the panel body. The panel body includes a substrate, a light-emitting device layer, and an encapsulation layer. The light-emitting device layer is disposed on the substrate and includes a plurality of light-emitting elements disposed on the substrate. The encapsulation layer is disposed on the substrate and covers the light-emitting device layer. The encapsulation film includes a first encapsulation portion covering a peripheral side of the panel body, one end of the first encapsulation portion covers a side surface of the substrate, another end thereof extends along a first direction and covers a side surface of the encapsulation layer, and the first direction is a direction in which the substrate points to the encapsulation layer.

### CROSS-REFERENCE TO RELATED APPLICATION

This application claims priority to Chinese Patent Application No. 202311071583.2, filed in the China National Intellectual Property Administration on Aug. 23, 2023, entitled “DISPLAY PANELS AND MANUFACTURING METHODS THEREOF, AND DISPLAY APPARATUSES”, the entire contents of which are incorporated herein by reference.

### FIELD OF INVENTION

The present invention relates to the field of display technologies, and in particular, to display panels and manufacturing methods thereof, and display apparatuses.

### BACKGROUND OF INVENTION

The mini light-emitting diode (Mini LED) direct display technology is a new generation display technology after liquid crystal display (LCD), organic light-emitting diode (OLED) display, and Mini LED backlight, and is one of hot spots in future display technologies.

Currently, in Mini LED display panels, after LEDs are formed on a substrate, an encapsulation adhesive is often covered on the substrate to encapsulate the LEDs, a circuit, and the like. However, water vapor may easily invade an interior of the Mini LED display panel from a side junction between the encapsulation adhesive and the substrate, causing the LEDs and the circuit to be corroded and fail.

### SUMMARY OF INVENTION

In view of the above, embodiments of the present disclosure provide display panels and manufacturing methods thereof, and display apparatuses.

An embodiment of the present disclosure provides a display panel, including a panel body and an encapsulation film disposed on the panel body. The panel body includes: a substrate; a light-emitting device layer, disposed on the substrate and including a plurality of light-emitting elements disposed on the substrate; and an encapsulation layer, disposed on the substrate and covering the light-emitting device layer. The encapsulation film includes a first encapsulation portion covering a peripheral side of the panel body, one end of the first encapsulation portion covers a side surface of the substrate, another end extends along a first direction and covers a side surface of the encapsulation layer, and the first direction is a direction in which the substrate points to the encapsulation layer.

According to the foregoing objective of the present disclosure, an embodiment of the present disclosure further provides a manufacturing method for a display panel, including the following steps: forming a plurality of light-emitting elements on a substrate, to form a light-emitting device layer; forming, on the substrate, an encapsulation layer covering the light-emitting device layer, to form a panel body; and forming an encapsulation film on the panel body, the encapsulation film including a first encapsulation portion covering a peripheral side of the panel body, one end of the first encapsulation portion covering a side surface of the substrate, another end extending along a first direction and covering a side surface of the encapsulation layer, and the first direction being a direction in which the substrate points to the encapsulation layer.

According to the foregoing objective of the present disclosure, an embodiment of the present disclosure further provides a display apparatus. The display apparatus includes at least one of the above display panels.

### BRIEF DESCRIPTION OF DRAWINGS

The following describes specific implementations of the present disclosure in detail with reference to the accompanying drawings, to make the technical solutions and other beneficial effects of the present disclosure obvious.

FIG. 1 is a schematic diagram of a structure of a display panel according to an embodiment of the present disclosure.

FIG. 2 is a flowchart of a manufacturing method for a display panel according to an embodiment of the present disclosure.

FIG. 3 to FIG. 6 are schematic structural diagrams of a manufacturing process of a display panel according to an embodiment of the present disclosure.

### DETAILED DESCRIPTION OF PREFERRED EMBODIMENTS

The following clearly and completely describes the technical solutions in embodiments of the present disclosure with reference to the accompanying drawings in the embodiments of the present disclosure. Obviously, the described embodiments are only some rather than all of the embodiments of the present disclosure. All other embodiments obtained by a person of skill in the art based on the embodiments of the present disclosure without creative efforts shall fall within the protection scope of the present disclosure.

Many different implementations or examples are provided in the following disclosure to implement different structures of the present disclosure. To simplify the disclosure of the present disclosure, components and settings in particular examples are described below. Certainly, they are merely examples and are not intended to limit the present disclosure. In addition, in the present disclosure, reference numerals and/or reference symbols may be repeated in different examples. The repetition is for the purposes of simplification and clearness, and does not in itself indicate a relationship between the discussed various implementations and/or configurations. Moreover, the present disclosure provides examples of various particular processes and materials, but a person of ordinary skill in the art may be aware of application of another process and/or use of another material.

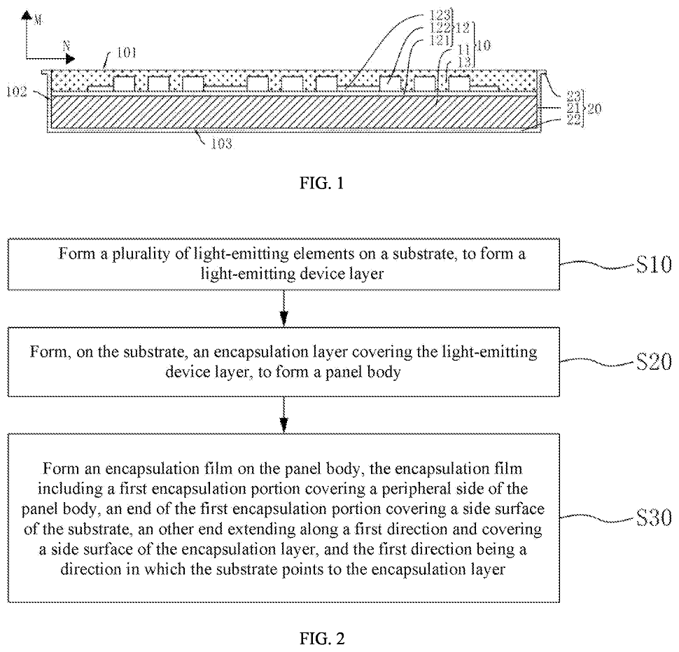

An embodiment of the present disclosure provides a display panel, referring to FIG. 1, the display panel includes a panel body 10 and an encapsulation film 20 disposed on the panel body 10.

The panel body 10 includes a substrate 11, a light-emitting device layer 12, and an encapsulation layer 13, where the light-emitting device layer 12 is disposed on the substrate 11 and includes a plurality of light-emitting elements 122 disposed on the substrate 11; and the encapsulation layer 13 is disposed on the substrate 11 and covers the light-emitting device layer 12.

Further, the encapsulation film 20 includes a first encapsulation portion 21 covering a peripheral side of the panel body 10, an end of the first encapsulation portion 21 covers a side surface of the substrate 11, another end extends along a first direction M and covers a side surface of the encapsulation layer 13, and the first direction M is a direction in which the substrate 11 points to the encapsulation layer 13.

In a process of implementing this application, in the present embodiment of the present disclosure, the encapsulation film 20 is disposed on the panel body 10, and the first encapsulation portion 21 in the encapsulation film 20 covers at least the peripheral side of the panel body 10. Specifically, an end of the first encapsulation portion 21 covers the side surface of the substrate 11, another end extends along the first direction M and covers the side surface of the encapsulation layer 13, and the first direction M is a direction in which the substrate 11 points to the encapsulation layer 13. In this way, a side junction between the encapsulation layer 13 and the substrate 11 is covered by the first encapsulation portion 21, which reduces a probability of water vapor intruding into an interior of the panel body 10 from the side junction between the encapsulation layer 13 and the substrate 11, reduces a probability of the light-emitting device layer 12 being corroded by the water vapor and failing, and improves a yield rate of the display panel.

Specifically, still referring to FIG. 1, the display panel includes a panel body 10 and an encapsulation film 20 disposed on the panel body 10. The encapsulation film 20 covers a part of a surface of the panel body 10 to encapsulate the panel body 10 and block the water vapor.

The panel body 10 includes a substrate 11, a light-emitting device layer 12 disposed on the substrate 11, and an encapsulation layer 13 disposed on the substrate 11 and covering the light-emitting device layer 12. The panel body 10 further includes a light-emitting surface 101 located on one side of the encapsulation layer 13 that is away from the light-emitting device layer 12.

Further, the light-emitting device layer 12 includes a wiring layer 121, a plurality of light-emitting elements 122, and a light shielding layer 123 that are disposed on the substrate 11. The plurality of light-emitting elements 122 may be divided into a plurality of light-emitting element groups, each light-emitting element group may include a plurality of light-emitting elements 122, and the light shielding layer 123 may be located between adjacent light-emitting element groups. The wiring layer 121 may include a circuit unit and a signal trace, the plurality of light-emitting elements 122 may be connected to the signal trace and to the circuit unit, and the plurality of light-emitting elements 122 may be actively driven or passively driven, which is not limited herein.

In an embodiment, the light-emitting element group may include three light-emitting elements 122. As shown in FIG. 1, the three light-emitting elements 122 may be a red LED, a green LED, and a blue LED respectively. The light shielding layer 123 may be a black matrix or ink, and a light-emitting direction of the light-emitting element 122 may be set toward the light-emitting surface 101.

The encapsulation layer 13 is disposed on the substrate 11 and covers the wiring layer 121, the plurality of light-emitting elements 122, and the light shielding layer 123. In the present embodiment of the present disclosure, water vapor is easily formed at the junction between the side surface of the encapsulation layer 13 and the side surface of the substrate 11 and invades a channel, making the wiring layer 121 and the light-emitting element 122 in the light-emitting device layer 12 susceptible to water vapor erosion and failure. Therefore, in the present embodiment of the present disclosure, the encapsulation film 20 is added and disposed on the panel body 10, the encapsulation film 20 includes a first encapsulation portion 21 covering a peripheral side of the panel body 10, an end of the first encapsulation portion 21 covers a side surface of the substrate 11, another end extends along a first direction M and covers a side surface of the encapsulation layer 13, and the first direction M is a direction in which the substrate 11 points to the encapsulation layer 13, so that the first encapsulation portion 21 may cover the junction between the side surface of the encapsulation layer 13 and the side surface of the substrate 11, to reduce a probability of water vapor intrusion and improve the yield rate of the display panel.

In an embodiment, the encapsulation layer 13 may include a transparent adhesive layer.

Further, the panel body 10 includes a light-emitting surface 101, a first surface 102 connected to the light-emitting surface 101 and located on the peripheral side of the panel body 10, and a second surface 103 disposed opposite to the light-emitting surface 101, where the first surface 102 is a side surface of the panel body 10, and the second surface 103 is a surface of one side of the substrate 11 that is away from the light-emitting device layer 12. The first encapsulation portion 21 is disposed around the panel body 10 and continuously covers the first surface 102 to reduce a probability of water vapor intruding into an interior of the panel body 10 from the side surface of the panel body 10 and improve the yield rate of the display panel.

A material of the encapsulation film 20 may include at least one of parylene, polyacrylate, and aluminum oxide. In addition, the water vapor transmission rate of the encapsulation film 20 is less than 10 g/m²·24H.

In an embodiment, the encapsulation film 20 further includes a second encapsulation portion 22 covering the second surface 103, that is, the second encapsulation portion 22 covers the surface of one side of the substrate 11 that is away from the light-emitting device layer 12, and the second encapsulation portion 22 may be connected to the first encapsulation portion 21, that is, the second encapsulation portion 22 may be integrally formed with the first encapsulation portion 21.

In an embodiment, the encapsulation film 20 further includes a third encapsulation portion 23, the third encapsulation portion 23 is connected to an end of the first encapsulation portion 21 that is close to the light-emitting surface 101, an end of the third encapsulation portion 23 is connected to the light-emitting surface 101, another end is disposed away from the first encapsulation portion 21 along a second direction N, and the second direction N intersects the first direction M. For example, the second direction N may be perpendicular to the first direction M.

In an embodiment, a length of the third encapsulation portion 23 along the second direction N may be greater than 0 micrometers and less than or equal to 100 micrometers, for example, may be 5 micrometers, 10 micrometers, 20 micrometers, 30 micrometers, 40 micrometers, 50 micrometers, 60 micrometers, 70 micrometers, 80 micrometers, 90 micrometers, or 100 micrometers.

Further, the third encapsulation portion 23 may also be integrally formed with the first encapsulation portion 21 and the second encapsulation portion 22.

It should be noted that the encapsulation film 20 may cover the first surface 102 and the second surface 103 of the panel body 10, that is, the encapsulation film 20 may cover the surface of the panel body 10 except the light-emitting surface 101, so as to prevent water vapor intrusion into the entire panel body 10. In addition, in the present embodiment of the present disclosure, the encapsulation film 20 does not cover the light-emitting surface 101 of the panel body 10, which can prevent the encapsulation film 20 from affecting the light emission of the panel body 10 and ensure a display effect of the display panel.

In addition, the encapsulation film 20 can be prepared by chemical vapor deposition, plasma chemical vapor deposition, or single atomic layer deposition, thereby obtaining a film with a small thickness and high density, so that the encapsulation film 20 has a small thickness and a better encapsulation effect, which can reduce a frame width of the display panel. When the display panel provided in the present embodiment of the present disclosure is used in a spliced display apparatus, a splicing seam in the spliced display apparatus can be effectively reduced, and a display effect of the spliced display apparatus may be improved.

In an embodiment, a thickness of the encapsulation film 20 may be greater than or equal to 5 micrometers and less than or equal to 50 micrometers, for example, may be 5 micrometers, 10 micrometers, 20 micrometers, 30 micrometers, 40 micrometers, or 50 micrometers.

Based on the above, in the present embodiment of the present disclosure, the encapsulation film 20 is disposed on the panel body 10, and the first encapsulation portion 21 in the encapsulation film 20 covers at least the peripheral side of the panel body 10. Specifically, an end of the first encapsulation portion 21 covers the side surface of the substrate 11, another end extends along the first direction M and covers the side surface of the encapsulation layer 13, and the first direction M is a direction in which the substrate 11 points to the encapsulation layer 13. In this way, a side junction between the encapsulation layer 13 and the substrate 11 is covered by the first encapsulation portion 21, which reduces a probability of water vapor intruding into an interior of the panel body 10 from the side junction between the encapsulation layer 13 and the substrate 11, reduces a probability of the light-emitting device layer 12 being corroded by the water vapor and failing, and improves a yield rate of the display panel.

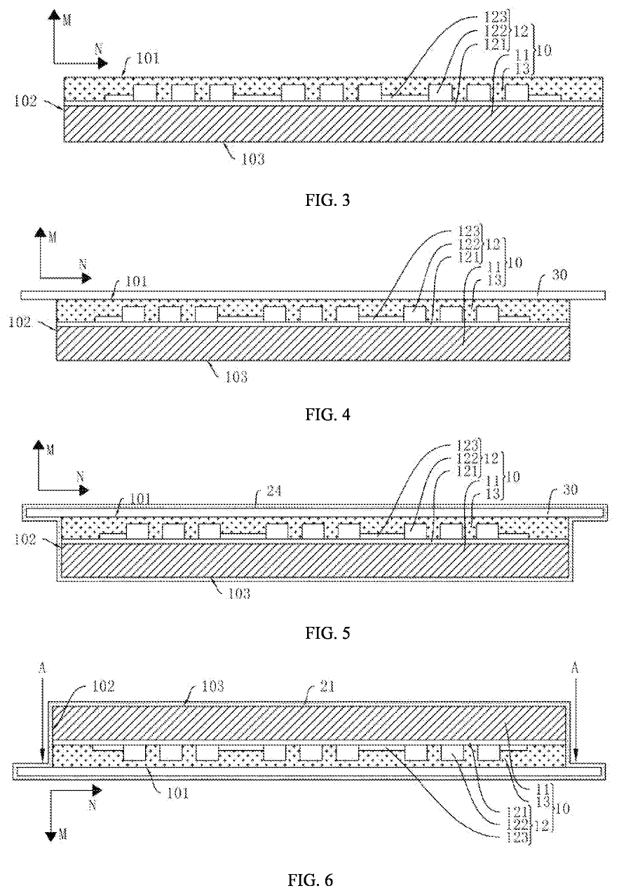

In addition, an embodiment of the present disclosure further provides a manufacturing method for a display panel. With reference to FIG. 1, FIG. 2, and FIG. 3 to FIG. 6, the manufacturing method for a display panel includes the following steps.

At S10, a plurality of light-emitting elements 122 are formed on a substrate 11, to form a light-emitting device layer 12.

At S20, an encapsulation layer 13 covering the light-emitting device layer 12 is formed on the substrate 11, to form a panel body 10.

At S30, an encapsulation film 20 is formed on the panel body 10, the encapsulation film 20 includes a first encapsulation portion 21 covering a peripheral side of the panel body 10, an end of the first encapsulation portion 21 covers a side surface of the substrate 11, another end thereof extends along a first direction M and covers a side surface of the encapsulation layer 13, and the first direction M is a direction in which the substrate 11 points to the encapsulation layer 13.

In step S10, the substrate 11 is provided, and the substrate 11 may be a glass substrate.

A wiring layer 121, a plurality of light-emitting elements 122, and a light shielding layer 123 are successively formed on the substrate 11 to form the light-emitting device layer 12. The plurality of light-emitting elements 122 may be divided into a plurality of light-emitting element groups, each light-emitting element group may include a plurality of light-emitting elements 122, and the light shielding layer 123 may be located between adjacent light-emitting element groups. The wiring layer 121 may include a circuit unit and a signal trace, the plurality of light-emitting elements 122 may be connected to the signal trace and to the circuit unit, and the plurality of light-emitting elements 122 may be actively driven or passively driven, which is not limited herein.

In an embodiment, the light-emitting element group may include three light-emitting elements 122. As shown in FIG. 1, the three light-emitting elements 122 may be a red LED, a green LED, and a blue LED respectively. The light shielding layer 123 may be a black matrix or ink.

In step S20, the encapsulation layer 13 is formed on the substrate 11, and the encapsulation layer 13 covers the light-emitting device layer 12 to form the panel body 10, as shown in FIG. 3. The encapsulation layer 13 may include a transparent adhesive layer.

In step S30, the panel body 10 includes a light-emitting surface 101 located on one side of the encapsulation layer 13 that is away from the light-emitting device layer 12, a first surface 102 connected to the light-emitting surface 101 and located on the peripheral side of the panel body 10, and a second surface 103 disposed opposite to the light-emitting surface 101. A protective layer 30 is formed on the light-emitting surface 101 of the panel body 10, and the protective layer 30 may cover the light-emitting surface 101 of the panel body 10 and partially extend outside the panel body 10 to form a suspended shape, as shown in FIG. 4.

In an embodiment, the protective layer 30 may be a UV visbreaking film.

Then, an encapsulation material layer 24 is formed to wrap the panel body 10 and the protective layer 30. The encapsulation material layer 24 covers the first surface 102 and the second surface 103 of the panel body 10, and a surface of the protective layer 30, as shown in FIG. 5.

In an embodiment, the chemical vapor deposition may be used to deposit parylene on the surfaces of the panel body 10 and the protective layer 30, or the plasma chemical vapor deposition may be used to deposit polyacrylate on the surfaces of the panel body 10 and the protective layer 30, or the single atomic layer deposition may be used to deposit an aluminum oxide material on the surfaces of the panel body 10 and the protective layer 30.

Next, the protective layer 30 and a portion of the encapsulation material layer 24 on a side of the protective layer 30 that is away from the light-emitting surface 101 are removed to form the encapsulation film 20.

Specifically, laser cutting or dicing machine cutting may be used to cut the protective layer 30 and the encapsulation material layer 24 according to an arrow A in FIG. 6. In order to avoid damage to the encapsulation material layer 24 on the first surface 102 in the cutting process, a safe distance needs to be reserved between a position of the arrow A and the encapsulation material layer 24 on the second surface 103, and the safe distance may be greater than 0 micrometers and less than or equal to 100 micrometers.

Then, the protective layer 30 is irradiated with UV light to peel off the protective layer 30 and the encapsulation material layer 24 located on one side of the protective layer 30 that is away from the light-emitting surface 101 to form the encapsulation film 20.

The encapsulation film 20 includes a first encapsulation portion 21 covering the first surface 102, a second encapsulation portion 22 covering the second surface 103, and a third encapsulation portion 23 connected to an end of the first encapsulation portion 21 that is close to the light-emitting surface 101. An end of the third encapsulation portion 23 is connected to the first encapsulation portion 21, another end extends along the second direction N, and the second direction N intersects the first direction M.

It can be understood that, since a safe distance needs to be reserved in the process of cutting the protective layer 30 and the encapsulation material layer 24, after cutting, the third encapsulation portion 23 remains at the end of the first encapsulation portion 21 that is close to the light-emitting surface 101, and the length of the third encapsulation portion 23 along the second direction N is greater than 0 micrometers and less than or equal to 100 micrometers.

It should be noted that in other embodiments of the present disclosure, the safe distance may not be reserved, and the third encapsulation portion 23 does not retained in the encapsulation film 20.

In addition, in the present embodiment of the present disclosure, the protective layer 30 is pre-configured to cover the light-emitting surface 101 of the panel body 10, so that when the protective layer 30 is subsequently removed, the encapsulation material layer 24 located on one side of the protective layer 30 that is away from the light-emitting surface 101 may be simultaneously removed, to prevent the formed encapsulation film 20 from affecting the light emission of the panel body 10, thereby ensuring the display effect of the display panel.

In addition, an embodiment of the present disclosure further provides a display apparatus. The display apparatus includes at least one display panel described in the foregoing embodiments.

In an embodiment, the display apparatus may be a spliced display apparatus, the display apparatus includes at least two display panels as described in the foregoing embodiments, and the at least two display panels are spliced. Since an encapsulation film 20 in the display panel provided in the present embodiment of the present disclosure has a smaller thickness and a better encapsulation effect, which can reduce the frame width of the display panel, thereby reducing the seam in the display apparatus and improving the display effect of the display apparatus.

Because the display panel provided in the foregoing embodiments of the present disclosure is configured, the display apparatus provided in the present embodiment of the present disclosure has same beneficial effects as the foregoing display panel.

Based on the above, the display apparatus provided in this embodiment of the present disclosure may be a sliced display apparatus. Since the encapsulation film 20 can be prepared by chemical vapor deposition, plasma chemical vapor deposition, or single atomic layer deposition, thereby obtaining a film with a small thickness and high density, so that the encapsulation film 20 has a small thickness and a better encapsulation effect, which can reduce a frame width of the display panel. When the display panel provided in the present embodiment of the present disclosure is used in a spliced display apparatus, a splicing seam in the spliced display apparatus can be effectively reduced, and a display effect of the spliced display apparatus may be improved.

In the above-mentioned embodiments, the description of each embodiment has its own emphasis, and parts not described in detail in a certain embodiment may be referred to the related description of other embodiments.

The display panel and the manufacturing method thereof, and the display apparatus provided in the embodiments of the present disclosure are described in detail above. The principle and implementations of the present disclosure are described herein through specific examples. The description about the embodiments of the present disclosure is merely provided to help understand the technical solutions and core ideas of the present disclosure. However, a person of the ordinary skill in the art should understand that modifications may still be made to the technical solutions described in the foregoing embodiments, or equivalent replacements may be made to the part of the technical features; and modifications or replacements will not cause the essence of corresponding technical solutions to depart from the scope of the technical solutions in the embodiments of the present disclosure.

What is claimed is:

1. A display panel, comprising a panel body and an encapsulation film disposed on the panel body, wherein the panel body comprises:
a substrate;
a light-emitting device layer, disposed on the substrate and comprising a plurality of light-emitting elements disposed on the substrate; and
an encapsulation layer, disposed on the substrate and covering the light-emitting device layer, and
wherein the encapsulation film comprises a first encapsulation portion covering a peripheral side of the panel body, one end of the first encapsulation portion covers a side surface of the substrate, another end of the first encapsulation portion extends along a first direction and covers a side surface of the encapsulation layer, and the first direction is a direction in which the substrate points to the encapsulation layer.

2. The display panel as claimed in claim 1, wherein the panel body comprises a light-emitting surface located at a side of the encapsulation layer away from the light-emitting device layer, and the panel body further comprises a first surface connected to the light-emitting surface and located at the peripheral side of the panel body, and
wherein the first encapsulation portion is disposed around the panel body, and continuously covers the first surface.

3. The display panel as claimed in claim 2, wherein the panel body further comprises a second surface disposed opposite to the light-emitting surface, and the second surface is a surface of the substrate away from the light-emitting device layer, and
wherein the encapsulation film further comprises a second encapsulation portion, and the second encapsulation portion covers the second surface.

4. The display panel as claimed in claim 3, wherein the first encapsulation portion is connected to the second encapsulation portion.

5. The display panel as claimed in claim 2, wherein the encapsulation film further comprises a third encapsulation portion, the third encapsulation portion is connected to the one end of the first encapsulation portion that is close to the light-emitting surface, one end of the third encapsulation portion is connected to the first encapsulation portion, another end of the third encapsulation portion is disposed away from the first encapsulation portion along a second direction, and the second direction intersects the first direction.

6. The display panel as claimed in claim 5, wherein a length of the third encapsulation portion along the second direction is greater than 0 micrometers and less than or equal to 100 micrometers.

7. The display panel as claimed in claim 1, wherein a material of the encapsulation film comprises at least one of parylene, polyacrylate, or aluminum oxide, and a thickness of the encapsulation film is greater than or equal to 5 micrometers and less than or equal to 50 micrometers.

8. A manufacturing method for a display panel, comprising the following steps:
forming a plurality of light-emitting elements on a substrate, to form a light-emitting device layer;
forming, on the substrate, an encapsulation layer covering the light-emitting device layer, to form a panel body; and
forming an encapsulation film on the panel body, the encapsulation film comprising a first encapsulation portion covering a peripheral side of the panel body, one end of the first encapsulation portion covering a side surface of the substrate, another end of the first encapsulation portion extending along a first direction and covering a side surface of the encapsulation layer, and the first direction being a direction in which the substrate points to the encapsulation layer.

9. The manufacturing method as claimed in claim 8, wherein the panel body comprising a light-emitting surface located at a side of the encapsulation layer away from the light-emitting device layer, and the step of forming the encapsulation film on the panel body comprises:
forming a protective layer on the light-emitting surface of the panel body;
forming an encapsulation material layer wrapping the panel body and the protective layer; and
removing the protective layer and a portion of the encapsulation material layer on a side surface of the protective layer away from the light-emitting surface, to form the encapsulation film.

10. A display apparatus comprising a display panel, wherein the display panel comprises a panel body and an encapsulation film disposed on the panel body, and the panel body comprises:
a substrate;
a light-emitting device layer, disposed on the substrate and comprising a plurality of light-emitting elements disposed on the substrate; and
an encapsulation layer, disposed on the substrate and covering the light-emitting device layer, and
wherein the encapsulation film comprises a first encapsulation portion covering a peripheral side of the panel body, one end of the first encapsulation portion covers a side surface of the substrate, another end of the first encapsulation portion extends along a first direction and covers a side surface of the encapsulation layer, and the first direction is a direction in which the substrate points to the encapsulation layer.

11. The display apparatus as claimed in claim 10, wherein the panel body comprises a light-emitting surface located at a side of the encapsulation layer away from the light-emitting device layer, and the panel body further comprises a first surface connected to the light-emitting surface and located at the peripheral side of the panel body, and
wherein the first encapsulation portion is disposed around the panel body, and continuously covers the first surface.

12. The display apparatus as claimed in claim 11, wherein the panel body further comprises a second surface disposed opposite to the light-emitting surface, and the second surface is a surface of the substrate away from the light-emitting device layer, and
wherein the encapsulation film further comprises a second encapsulation portion, and the second encapsulation portion covers the second surface.

13. The display apparatus as claimed in claim 12, wherein the first encapsulation portion is connected to the second encapsulation portion.

14. The display apparatus as claimed in claim 11, wherein the encapsulation film further comprises a third encapsulation portion, the third encapsulation portion is connected to the one end of the first encapsulation portion that is close to the light-emitting surface, one end of the third encapsulation portion is connected to the first encapsulation portion, another end of the third encapsulation portion is disposed away from the first encapsulation portion along a second direction, and the second direction intersects the first direction.

15. The display apparatus as claimed in claim 14, wherein a length of the third encapsulation portion along the second direction is greater than 0 micrometers and less than or equal to 100 micrometers.

16. The display apparatus as claimed in claim 10, wherein a material of the encapsulation film comprises at least one of parylene, polyacrylate, or aluminum oxide, and a thickness of the encapsulation film is greater than or equal to 5 micrometers and less than or equal to 50 micrometers.
